(19) United States
(12) Patent Application Publication
(10) Pub. No.: US 2024/0070348 A1
(43) Pub. Date: Feb. 29, 2024

(54) COMPUTER-IMPLEMENTED METHOD FOR DETERMINING A SPATIAL DISTRIBUTION OF ELEMENT SIZE VALUES FOR GEOMETRIC BASIC ELEMENTS OF A NETWORK DISPLAY FROM A DIGITAL DISPLAY OF AN OBJECT FOR A SIMULATION OF THE OBJECT

(71) Applicant: VOLUME GRAPHICS GMBH, Heidelberg (DE)

(72) Inventors: Kai SALM, Heidelberg (DE); Johannes FIERES, Heidelberg (DE)

(21) Appl. No.: 18/548,792

(22) PCT Filed: Feb. 24, 2022
(86) PCT No.: PCT/EP2022/054646

§ 371 Date: Sep. 1, 2023

(30) Foreign Application Priority Data
Mar. 1, 2021 (DE) 10 2021 104 886.9

(51) Int. Cl. G06F 30/20

(52) U.S. Cl. CPC G06F 30/20

(57) ABSTRACT

Method for determining a spatial distribution of element size values for geometric basic elements of a network display from a digital display of an object for a simulation of the object, wherein the network display contains interconnected geometric basic elements. The method including: determining a digital display of an object; determining, for at least one position of the digital display, at least one local maximum limit for the element size values that depends on at least one local geometric property in an area surrounding the position: determining, for the digital display, a predefined spatial distribution of an upper limit, independent of the maximum limit, for the element size values and a predefined spatial distribution of a maximum spatial change in the element size values; and determining a spatial distribution of element size values for the digital display based on the maximum limit, and the two predefined spatial distributions.

### BACKGROUND

### Field

The invention relates to a computer-implemented method for determining a spatial distribution of element size values for geometric basic elements of a mesh representation from a digital representation of an object for a simulation of the object.

### Description of the Related Art

The products of a computed tomographic (CT) measurement can be used for non-destructively inspecting manufactured products. A finite element (FEM) analysis of the geometry of the product measured with the CT measurement can be carried out for a numerical simulation of the physical, for example, mechanical, properties of the product. For this purpose, a suitable mesh must be created, which provides a reproduction of the geometry of the product. The mesh is formed from a plurality of geometric basic elements. These geometric basic elements can typically be composed of small primitives, for example, tetrahedrons, which can be connected to their direct neighbors via a common face, a common edge or a common corner point. The simulation of the relevant, possibly local, physical properties of the product can be carried out on the basis of the mesh.

For this purpose, the mesh must meet a few requirements. According to a first requirement, the elements of the mesh in relevant areas of the product must be selected to be so small that the effects to be simulated can be realistically reproduced. Examples thereof are surfaces and/or boundary surfaces having small curvatures, which are generally associated with small geometries that must be simulated; surroundings of small defects in the interior of the geometry; areas, in which high values of or changes in the simulated physical quantities across the space arise; areas, in which the user strives for a particularly high spatial resolution of the simulation results. An excessively large element size in these areas can result in a faulty reproduction of the real geometry of the product to be inspected or in an insufficient resolution of the simulating effects, and thus to an insufficiently accurate simulation of the product. According to one further requirement, the number of elements is to be kept as low as possible, in order to reduce the computing times in the simulation. A small element size is associated with a large number of elements. For this reason, it is sought to locally select an element size that is as large as possible, provided that the other requirements are met. According to one further requirement, a sufficiently good mesh quality is necessary for a simulation that is physically realistic and can actually be numerically carried out. This is usually quantified using characteristic numbers of the element shape, for example, the ratio of the longest element edge to the shortest element edge. Specifically which characteristic numbers are used and which limiting values of these characteristic numbers represent a barely acceptable level of quality depends on various factors, for example, on the software product used for the simulation and on the quality standards of the user. A mesh of tetrahedrons that are as regular as possible is often considered to be ideal. In practical application, in particular with complex geometries, a compromise must be found between mesh quality, shape accuracy and, possibly, further requirements. An optimization method is often applied starting from an initial mesh in order to iteratively approximate the best possible compromise.

For a tetrahedral mesh, the local change in element size can be determined, i.e., the extent to which adjacent elements differ from each other in terms of size. The local change in element size, in particular its global maximum, can act directly as a quality indicator, since it can affect the numerical stability of the calculations. Moreover, the change in element size of an initial mesh can also affect the optima of other characteristic numbers that are achievable in an interactive optimization method, for example, the ratio of the longest element edge to the shortest element edge.

The limitation of the change in element size is ideally made consistent with the other aforementioned conditions that relate to the element size.

U.S. Pat. No. 8,384,716 B2 describes a mesh generation method for image data sampled from an actual object, in which the mesh resolution can vary locally within the mesh. The method includes computer-implemented instructions that calculate a variable sampling point distribution in the image data space, the variable sampling point distribution having localized variations in the sampling point distribution within the image data space. Varying the mesh resolution can enable smaller elements to be located in regions of particular interest or activity when subsequently performing an analysis using the mesh model.

The problem addressed by the invention is therefore to provide an improved computer-implemented method for determining a spatial distribution of element size values for geometric basic elements of a mesh representation from a digital representation of an object for a simulation of the object, the method determining element sizes for the mesh representation such that, when using the mesh representation, computing time is reduced and the quality of the simulation results is improved.

### SUMMARY

Main features of the invention are described in claims 1 and 16. Embodiments are the subject matter of claims 2 through 15.

According to the invention, a computer-implemented method is provided for determining a spatial distribution of element size values for geometric basic elements of a mesh representation from a digital representation of an object for a simulation of the object, wherein the mesh representation contains a plurality of interconnected geometric basic elements, the method including the following steps: determining a digital representation of an object; determining, for at least one position of the digital representation of the object, at least one local maximum limit for the element size values that depends on at least one local geometric property in an area surrounding the position; determining, for the digital representation of the object, a predefined spatial distribution of an upper limit, independent of the at least one maximum limit, for the element size values and a predefined spatial distribution of a maximum spatial change in the element size values; and determining a spatial distribution of element size values for the digital object representation on the basis of the local maximum limit, the predefined spatial distribution of the upper limit and the predefined spatial distribution of the maximum spatial change.

An element size value is understood to be the size of a geometric basic element of a mesh representation. The element size value can be defined, for example, as the diameter of a bounding sphere around the geometric basic element or an inscribed sphere in the geometric basic element. In addition, the element size value can be defined, for example, as the diameter of the geometric basic element in the direction in which this diameter is the maximum, as the minimum or maximum edge length of the geometric basic element, or as the volume of the geometric basic element or the cube root of the volume, in order to obtain a one-dimensional length.

According to the invention, initially, for the digital object representation or an area of the digital object representation, for which a mesh is to be created, a value is determined for a local maximum limit for the element size values of the geometric basic elements, values for an upper limit of the element size values independent of the local maximum limit, and values for a maximum spatial change in the element size values. The achievable mesh quality is improved due to the limitation of the change in the element size in the creation of a mesh, in particular also the creation of an initial mesh with the objective of iterative optimization.

The upper limit of the local element size values is provided as a predefined spatial distribution for the digital representation of the object. The upper limit of the local element size values can be determined, for example, by a user, from minimum requirements on the simulation accuracy, wherein limiting values for the necessary spatial resolution of the simulation results can be derived from the determination. The upper limit for the element size values prevents excessively large geometric basic elements from occurring in the mesh, which could result in an impairment of the accuracy of the simulation results.

For this purpose, the local maximum limit is determined at at least one position in the digital object representation and depends on at least one local geometric property in an area surrounding the position. These geometric properties indirectly place locally varying requirements on the element size values. The local maximum limit is therefore determined depending on local conditions of the object, which can differ greatly between various objects of a similar type and also within an object.

The maximum spatial change in the element size values relates to the change in the element size values between spatially adjacent geometric basic elements of the mesh representation. The maximum spatial change can be derived from requirements on the quality of the mesh.

The spatial distribution of the element size values across the digital object representation is then determined from the local maximum limit, the upper limit and the maximum spatial change. The mesh representation can then be created on the basis of the spatial distribution of the element size values. The invention therefore provides a computer-implemented method, which determines a spatial distribution of the element size values for a mesh representation. On the basis of this distribution of the element size values, an appropriate mesh representation is subsequently created, which, when used, reduces the computing time and improves the quality of the simulation results.

The invention is particularly advantageous when the object is a multi-material object, in particular when the materials have very different geometric or material properties, which therefore place different requirements on the mesh representation. In addition, the invention is particularly advantageous when objects having many small pores are inspected, the realistic enmeshment of which could be difficult using conventional methods or would require an extremely large number of geometric basic elements. The invention is also particularly advantageous when objects having complex geometries are used in general or when particular requirements must be placed on the mesh representation in certain areas of the object due to requirements on the simulation results, user experience or other specifications.

According to one example, the method can also include the following step: determining, for the digital representation of the object, a predefined spatial distribution of a lower limit for the element size value, which is additionally a lower limit for the local maximum limit.

Therefore, a lower limit for the element size values is also determined, on which the determination of the spatial distribution of the element size values in the step: determining a spatial distribution of element size values for the digital object representation on the basis of the local maximum limit, the predefined spatial distribution of the upper limit and the predefined spatial distribution of the maximum spatial change, can additionally be based. Therefore, a corridor arises between the upper limit and the lower limit, in which the element size values can be located, said corridor being distributed across the digital representation of the object. The predefined spatial distribution of the lower limit can be determined from requirements on the computing time. Similarly to the upper limit, this requirement is to prevent excessively small geometric basic elements from occurring in the mesh representation. As a result, the computing time and the memory requirement for the simulation would become disproportionately great.

In one further example, the step of determining a spatial distribution of element size values can include the following substep: determining, for each position of the digital representation of the object, a maximum possible element size value, which is based at least on the local maximum limit, the predefined spatial distribution of the upper limit and the predefined spatial distribution of the maximum spatial change.

Therefore, the element size values are determined such that these assume the greatest value at every location that is permitted at least by the upper limit, the local maximum value and the maximum spatial change. The computing time of a simulation is therefore kept as short as possible.

It is also conceivable that the step of determining a spatial distribution of element size values on the basis of the local maximum limit, the predefined spatial distribution of the upper limit and the predefined spatial distribution of the maximum spatial change includes, for example, the following substeps: Setting at least one fixed point for an element size value at at least one position in the digital representation of the object at the local maximum limit when a local maximum limit has been determined for this at least one position in the digital representation; setting at least one fixed point for an element size value at at least one further position in the digital representation of the object that has a value of, at most, the upper limit; and determining the spatial distribution of element size values on the basis of the fixed points and the spatial distribution of the maximum spatial change.

If a lower limit has been defined, the lower limit can also be taken into account in these substeps, in particular in the substep: setting at least one fixed point for an element size value at at least one position in the digital representation of the object at the local maximum limit when a local maximum limit has been determined for this at least one position in the digital representation. The setting of fixed points at the various positions can be carried out in any order. This means, the substeps: setting at least one fixed point for an element size value at at least one position in the digital representation of the object at the local maximum limit when a local maximum limit has been determined for this at least one position in the digital representation; and setting at least one fixed point for an element size value at at least one further position in the digital representation of the object that has a value of, at most, the upper limit, can be carried out in any order, also simultaneously and multiple times one after the other. In addition, for example, in the substep: setting at least one fixed point for an element size value at at least one position in the digital representation of the object at the local maximum limit when a local maximum limit has been determined for this at least one position in the digital representation, individual points are identified, at which fixed points do not need to be set when, for example, the local maximum value is above the upper limit. By means of the fixed points, in combination with the maximum spatial change, a spatial distribution of element size values can be determined. For example, the spatial distribution of the element size values can be interpolated between the fixed points by means of the maximum spatial resolution. The spatial distribution of the element size values can also be, for example, preliminary and refined or optimized by means of the following steps and substeps.

According to another example, the substep: setting at least one fixed point for an element size value at at least one further position in the digital representation of the object that has a value of, at most, the upper limit, can include the following sub-substep: setting at least one fixed point for an element size value at the upper limit at at least one position in the digital representation of the object, at which the spatial distribution of the upper limit has a discontinuity.

The predefined spatial distribution of the upper limit can be provided discretely for a plurality of positions in the digital representation of the object. The positions can be areas, wherein an upper limit is not predefined between the areas. Setting the fixed points at the upper limit brings about a correction of the fixed points in areas, in which the spatial progression of the upper limit is discontinuous. This substep is particularly advantageous when initially only the following substep is carried out: setting at least one fixed point for an element size value at at least one position in the digital representation of the object at the local maximum limit when a local maximum limit has been determined for this at least one position in the digital representation. A fixed point having the local value of the upper limit can then also be preventively set at all positions, at which a fixed point could be needed. These are the areas at which the upper limit is not continuous, for example, the edges of areas, for which an upper limit has been defined. Computing time can be saved in this way.

In addition, the substep: setting at least one fixed point for an element size value at at least one further position in the digital representation of the object that has a value of, at most, the upper limit, can include, for example, the following sub-substeps: determining a spatial distribution of preliminary element size values in the digital representation of the object on the basis of the fixed points that were determined in the substep of setting at least one fixed point for an element size value at at least one position in the digital representation of the object at the local maximum level when a local maximum level has been set for this at least one position in the digital representation, and the spatial distribution of the maximum spatial change; setting the preliminary element size values at the upper limit at positions in the digital representation of the object, at which the preliminary element size values are greater than the upper limit; and setting at least one fixed point for an element size value at the preliminary element size value at at least one position in the digital representation of the object, at which the spatial distribution of the upper limit and/or the spatial distribution of the preliminary element size values has a discontinuity.

The spatial distribution of the preliminary element size values is therefore determined on the basis of the fixed points that were determined by means of the local maximum limit and the maximum spatial change. This is then limited upwardly by means of the upper limit. New fixed points can be set in areas, in which the upper limit is discontinuous, for example, the edges of the areas, in which the upper limit has been defined, and/or the spatial distribution of the preliminary element size values is discontinuous. The value of these fixed points is the determined value of the element size values that is limited by the upper limit.

In general, these fixed points can be set anywhere in which the derivative or the slope of the spatial distribution of the upper limit is greater than the maximum spatial change. If extended areas having a constant upper limit are used, setting these new fixed points can be limited to discontinuous ranges of the spatial distribution of the upper limit.

According to one further example, only the element size values are set as further fixed points, at which the upper limit is discontinuous and at which the element size values must be adapted due to the upper limit.

In the three-dimensional case, the fixed points are not only individual points, but rather usually positioned along the edges of the areas, at which an upper limit has been defined, and thus form the surfaces of these areas. A surface portion can therefore also be referred to as a fixed point. The distribution of element size values and also the fixed points can therefore also be defined or calculated in a three-dimensional voxel grid. As a result, a comparatively large number of voxels can still be required in three dimensions in order to describe all voxels on these surfaces as fixed points. However, this number is still considerably less than the total number of voxels in the volume of the digital representation of the object.

At an overlap or contact between areas, in which an upper limit has been predefined, only one, preferably the lower, upper limit of the two upper limits is used at the position for setting the corresponding fixed point.

Not all possible fixed points need to be set. Instead, positions, at which a fixed point could be set, can also be omitted.

According to one further example, the step of determining a spatial distribution of element size values can also include the following substep: removing the fixed point when the fixed point is greater than an element size value determined for the position of the fixed point and/or when the fixed point is greater than or equal to an element size value determined for the position of the fixed point by means of at least one further fixed point.

This substep can be a standalone step that inspects and, if necessary, removes fixed points that have already been set. Alternatively or additionally, this substep can also be carried out during the setting of the fixed points and integrated in the corresponding step.

Regardless of which of the aforementioned sub-substeps of the substep: removing the fixed point when the fixed point is greater than an element size value determined for the position of the fixed point and/or when the fixed point is greater than or equal to an element size value determined for the position of the fixed point by means of at least one further fixed point, is used, the number of fixed points can be minimized at various points in time and, thus, the computing time can be minimized.

Not all fixed points result in new conditions for the simulation, for example, when one further, nearby fixed point having a lower value in the surroundings also stipulates these conditions. For example, fixed points are not necessary that, under consideration of the maximum spatial change, are greater than the greatest possible element size value at this position. In addition, for example, fixed points that do not bring about a change in the spatial progression of the element size values, are also not absolutely necessary.

The following conditions therefore result when a fixed point is not required: when the spatial distribution of the element size values determined on the basis of all fixed points results in a lower value at this position or when the distribution of the element size values determined on the basis of at least one other fixed point results in a lower value or the same value at this point. With reference to these specifications, a check can therefore be carried out during the setting of a fixed point to determine whether this is even required. Alternatively, a check can also be carried out afterwards to determine whether fixed points can be removed again. This has the advantage that computing time can be saved at a later point in time during the calculation of the distribution of the element size values for the entire space, since fewer fixed points need to be taken into account.

For example, only those element size values at positions, at which the upper limit is discontinuous, can be set as fixed points, which have been adapted due to the upper limit. This minimizes the number of fixed points.

According to one further example, after the new fixed points have been set at the edges of the areas, in which an upper limit has been predefined, a check can be carried out for all fixed points to determine whether these can be removed. For example, a check can be carried out for the fixed point having the lowest value to determine whether other fixed points become superfluous due said fixed point and the other fixed points are then removed. This can be repeated for as long as it takes until all fixed points have been checked.

It is also conceivable that the step of determining a spatial distribution of element size values after the substep of determining the spatial distribution of element size values on the basis of the fixed points and the spatial distribution of the maximum spatial change can include, for example, the following substeps: setting the element size values of the determined spatial distribution of element size values, which are greater than the upper limit for the same position, on the upper limit.

In the substep: determining the spatial distribution of element size values on the basis of the fixed points and the spatial distribution of the maximum spatial change, the upper limit is not yet taken into account. By means of the subsequent substep: setting the element size values of the determined spatial distribution of element size values, which are greater than the upper limit for the same position, on the upper limit, the determined spatial distribution of the element size values is limited by the upper limit. Element size values that are above the upper limit are therefore corrected.

At least one of the following substeps: setting at least one fixed point for an element size value at at least one further position in the digital representation of the object that has a value of, at most, the upper limit; and/or determining the spatial distribution of element size values on the basis of the fixed points and the spatial distribution of the maximum spatial change; can also include, for example, the following sub-substep: storing the set fixed points in a priority queue.

The processing of the fixed points for determining the spatial distribution of the element size values can therefore be optimized.

It is also conceivable, for example, that the step of determining a spatial distribution of element size values for the digital object representation on the basis of the local maximum limit, the predefined spatial distribution of the upper limit and the predefined spatial distribution of the maximum spatial change can include the following substeps: dividing the digital object representation into at least two areas, wherein, in each case, at least two areas are interconnected by means of a border region; determining element size values for at least one position in at least one border region; setting at least one determined element size value as a fixed point at the at least one position in the at least one border region; and determining a spatial distribution of element size values for at least one of the at least two areas separately on the basis of the fixed points of the previous substep and, when further fixed points are located in the area, preferably on the further fixed points.

As soon as the fixed points in the border regions have been determined for every individual area, said fixed points can be reduced for each area separately, for example, back to the absolutely necessary fixed points, as described above, in order to accelerate the calculation of the spatial distribution of the element size values in the individual areas.

The entire volume can be subdivided, for example, into box-shaped areas. Alternatively, the areas can be advantageously selected such that fixed points must be set in their border regions anyway, for example, when the edges of areas, in which an upper limit has been defined, are selected as border regions.

In addition, the positions and the values of the particular dominating fixed points can be noted in each point of the border region. The calculation can then be carried out in the interior without any further information about the outer area.

The step of determining a spatial distribution of element size values for the digital object representation on the basis of the local maximum limit, the predefined spatial distribution of the upper limit and the predefined spatial distribution of the maximum spatial change according to one further example can also include the following substeps: setting at least one fixed point for an element size value at at least one position in the digital representation of the object at the local maximum limit when a local maximum limit has been determined for this at least one position in the digital representation, and/or setting at least one fixed point for an element size value at at least one position in the digital representation of the object that has a value of, at most, the upper limit; dividing the digital representation of the object into at least two areas, wherein, in each case, at least two areas are interconnected by means of a border region; determining at least one border region fixed point for at least one position in the at least one border region on the basis of the previously determined fixed points outside the border region, wherein, for each border region fixed point value, an element size value and/or a piece of information about at least one previously determined fixed point, which is decisive for the particular border region fixed point, is determined and stored; and determining a spatial distribution of element size values for at least one of the two areas separately on the basis of the at least one border region fixed point and, when further fixed points area located in the area, preferably on the further fixed points.

By means of the substeps of this example, identical or numerically more precise results can be achieved without explicitly calculating the element size values for the fixed points by using the alternative that only information about at least one previously determined fixed point, which is decisive for the particular border region fixed point, is used. When information about which original fixed point(s) is/are decisive for the element size value is stored for each of the corresponding fixed points in the border region of an area, this information can be used to efficiently calculate the element size values of the entire area.

In this example as well, however, the positions and the values of the particular dominating fixed points can be noted in each point of the border region, in the first alternative. The calculation can then be carried out in the interior without any further information about the outer area.

According to another example, the step of determining, for at least one position of the digital representation of the object, a local maximum limit for the element size value that depends on at least one local geometric property in an area surrounding the position, can include the following substep: determining the local maximum limit for the position on the basis of a local curvature of a surface of the digital representation of the object at the position, a local wall thickness of the digital representation of the object at the position and/or a previously carried out simulation result for the object.

In addition, the digital representation of the object can have, for example, a multi-material geometry, wherein the spatial distribution of the upper limit, the spatial distribution of the maximum local change in the element size values and/or the step of determining, for at least one position of the digital representation of the object, a local maximum limit for the element size value that depends on at least one local geometric property in an area surrounding the position, are material-dependent.

The digital representation of the object can be determined, for example, by means of a computed tomographic measurement of the object.

In addition, the determined spatial distribution of the element size values on the basis of the predefined spatial distribution of the maximum spatial change can have, for example, a Lipschitz constant.

Preferably, the Lipschitz constant is globally defined and constant. The Lipschitz constant can also be defined locally or in a material-dependent manner, however.

The method in one further example can also include the following steps: determining a spatial distribution of geometric basic elements for a mesh representation of the digital representation of the object on the basis of the determined spatial distribution of element size values; and determining a mesh representation for the digital representation of the object from geometric basic elements on the basis of the determined spatial distribution of geometric basic elements.

Therefore, a mesh representation is determined from the spatial distribution of the element size values across the spatial distribution of geometric basic elements.

According to one further example, the spatial distribution of the element size values can be determined for the entire volume of the digital representation of the object to be enmeshed. Alternatively, the spatial distribution of the element size values can be determined only for a portion of the digital representation of the object.

The spatial distribution of the element size values can be determined, for example, “on demand” for a position or a point in the digital representation of the object.

In addition, the lower limit and/or the upper limit can be, for example, locally defined.

According to one further example, a geometry of defects in the interior of the digital object representation can be derived from a separate analysis of measured values, which can be, for example, gray values of a CT measurement. Advantageously, different algorithms can be used for the defect analysis and for surface determination.

In addition, for example, defects below a certain limiting size can be ignored during enmeshment. The geometry is then not adapted and the defect at the local maximum level is not taken into account as a local geometric property. The relevant defect can, for example, be taken into account instead due to changed material properties in the geometric basic element or the corresponding geometric basic element. During enmeshment, for example, care can be taken to ensure that the defect is arranged in the center of a geometric basic element to the greatest extent possible.

According to one further example, the limiting size can be locally defined and depend on at least the local wall thickness, the material properties and/or the distance to the next boundary surface.

The values of the local maximum limit can be limited, for example, to the upper limit before starting the calculations of the spatial distribution of the element size values. Similarly, the values of the lower limit can be limited, for example, to the upper limit. If a lower limit at one position has been, for example, erroneously defined as greater than the upper limit, this can therefore be corrected.

The invention further relates to a computer program product having instructions, which can be carried out on a computer and, when carried out on a computer, prompt the computer to carry out the method according to the preceding description.

Advantages and effects as well as developments of the computer program product will become apparent from the advantages and effects as well as developments of the above-described method. Reference is therefore made to the preceding description in this regard. A computer program product can be understood to be, for example, a data carrier, on which a computer program element is stored, which includes instructions which can be carried out for a computer. Alternatively or additionally, a computer program product can also be understood to be, for example, a permanent or volatile data memory, such as a flash memory or random access memory, which includes the computer program element. Further types of data memories that include the computer program element are therefore not ruled out, however.

Further features, details, and advantages of the invention will become apparent from the wording of the claims and from the following description of exemplary embodiments with reference to the drawings, wherein:

### DESCRIPTION OF THE DRAWINGS

FIG. 1 shows a flowchart of the computer-implemented method; and

FIGS. 2a-d show a schematic diagram across the spatial progression of the upper limit, the lower limit and the local maximum values in the object.

### DETAILED DESCRIPTION

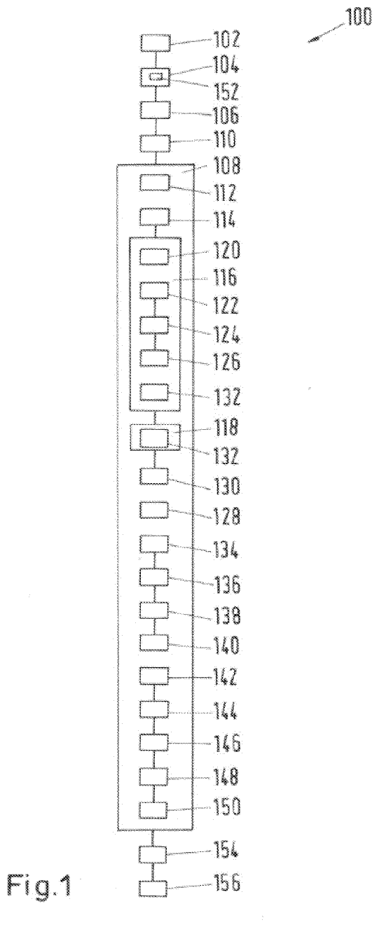

FIG. 1 shows the computer-implemented method 100 for determining a spatial distribution of element size values for geometric basic elements of a mesh representation from a digital representation of an object for a simulation of the object. The element size values indicate the size of the geometric basic elements of the mesh representation. The mesh representation as a whole simulates at least one portion of the digital representation of the object, which can also be referred to as a digital object representation.

The mesh representation contains a plurality of geometric basic elements. The geometric basic elements are interconnected to form a mesh representation. The mesh representation is then to be used to simulate the material properties of the object. This simulation can be created, for example, by means of a finite element calculation.

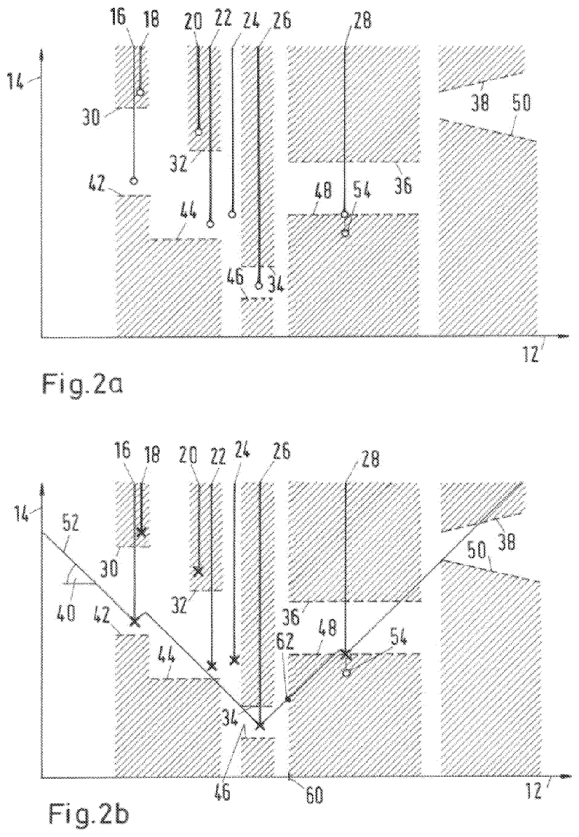

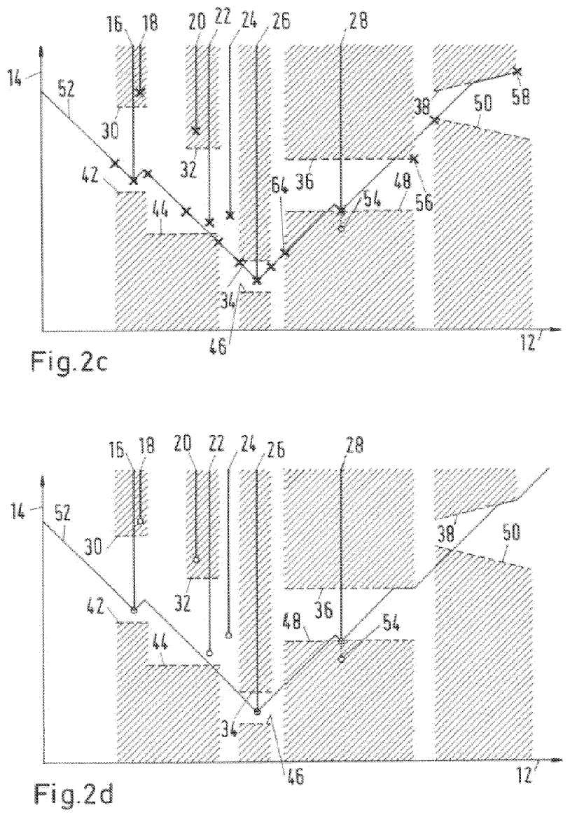

The steps of the method 100 are explained in greater detail in the following with reference, in part, to FIGS. 2a through 2d. Mention is therefore made in the meantime, in the following description, to FIGS. 2a through 2d, in order to then further explain the steps according to FIG. 1.

FIGS. 2a through 2d show a one-dimensional representation of a position in the digital object representation. It is to be mentioned that the digital object representation is generally a three-dimensional representation and the spatial distribution of the element size values is also three-dimensional. For the sake of simplicity, however, the following explanation is based on the one-dimensional representation.

The horizontal axis 12 indicates the position in the digital object representation. The vertical axis 14 indicates the size of the element size values.

In a first step 102, the method 100 includes determining a digital representation of an object. This determination can be carried out, for example, by means of a computed tomographic measurement of the object.

In one further step 104, a local maximum limit for the element size value at a position can be determined for this at least one position of the digital representation of the object.

In FIG. 2a, the local maximum value is indicated by a small circle, for example, at the positions 16 through 28. The line that extends vertically upward from the small circle is intended to indicate that element size values are to be prohibited above the small circle at that position.

This determination of the local maximum limit depends on at least one geometric property in the area surrounding the position or in the position itself. This means, the geometric property does not necessarily need to be arranged at the same position as the element size value for which the local maximum limit is to be determined. Geometric properties can be, for example, image fidelity or numerical requirements with respect to certain geometric features, a local wall thickness between boundary surfaces and/or a distance to the next boundary surface.

With regard to the local wall thickness, the following applies: The smaller the wall thickness is, the smaller the elements and, therefore, the local maximum limit must be, in order to be able to model the material along this wall thickness with a sufficient number of geometric basic elements.

The distance to the nearest boundary surface defines a depth in the material of the object. The greater the depth in the material is, the larger the geometric basic elements and, therefore, the local maximum limit can tend to be, since the relevant processes usually take place in the surroundings of the boundary surface.

In addition, the local maximum limit can therefore be determined, for example, in an optional substep 152 from a local curvature of a boundary surface or surface and/or from a local simulation result from a previous simulation of the object and one further material property that is not taken into account by any other conditions of the method 100.

A large curvature means that small geometries occur in this area that must be reproduced using small geometric basic elements. The greater the curvature or the smaller the radii of curvature is/are in the surrounding area, the lower will be the local maximum limit.

With regard to the local simulation result from a previous simulation, it can be established that relevant simulation results arise in an area, which, for example, are relevant for a qualitative evaluation of the object or must be simulated with greater resolution, for example, when high tensions arise in a mechanical simulation or high gradients arise in the simulation result, the local maximum limit can be selected to be smaller in order to obtain more accurate results in a subsequent simulation. The previous simulation can be carried out on CAD, other measured data thereof or similar objects or even on a previous mesh representation of the same original geometry. This previous simulation can be advantageously also carried out using simulation methods that do not require meshes, but rather are based, for example, on an implicit representation of a geometry, for example, a distance field, or on image data. The local maximum limit can also take the material properties into account, for example, when the material properties are not taken into account by other values, such as, for example, the upper limit. A lower local maximum limit can be selected, for example, in a mechanical simulation for areas of high strength, since these areas typically absorb the tension.

According to one further step 106 of the method 100, for the digital representation of the object, a predefined spatial distribution of an upper limit for the element size values, which is independent of the at least one local maximum limit, and a predefined spatial distribution of a maximum spatial change in the element size values are determined.

In FIG. 2a, multiple ranges 30 through 38 are shown, each of which represents an upper limit. The dashed line in each case represents the particular upper limit. The shading above the dashed line represents an area, in which element size values are not to be located. Globally constant upper limits are predefined in each of the ranges 30 through 36. An upper limit is defined in the range 38, which increases from left to right and, thus, is not constant. Ranges, in which an upper limit has not been defined, can be arranged between the ranges 30 through 38. The upper limit is discontinuous at the transition from one range 30 through 38 to a range therebetween. When ranges, in which an upper limit is defined, are adjacently arranged, the upper limit between these ranges can also be discontinuous.

The upper limit of the local element size values is provided as a predefined spatial distribution for the digital representation of the object. The upper limit of the local element size values can be determined, for example, by a user, from minimum requirements on the simulation accuracy, wherein limiting values for the necessary spatial resolution of the simulation results can be derived from the determination. Advantageously, a global value can be predefined for the upper limit. In relevant areas, in which, for example, the results of the simulation are required with a higher resolution or the properties or effects to be simulated are to be reproduced with increased accuracy, a lower value for the upper limit can advantageously be defined, for example, locally, as the global upper limit. The upper limit can be predefined by a user or by an evaluation plan. In addition, the upper limit can be defined, for example, in a material-specific manner.

FIG. 2b shows a spatial progression of the element size values, which is indicated by the reference sign 52. The maximum spatial change is the absolute value of the maximum slope of the spatial progression. This is represented as an angle 40, which indicates the maximum angle with respect to the horizontal that the spatial progression of the element size values is permitted to have. A steeper progression is therefore to be avoided.

The derived or predefined spatial progressions of the maximum spatial change can be predefined by a user or an evaluation specification. The maximum spatial change can preferably be globally defined, since local quality differences are unfavorable for the simulation. Excessively great changes in the element size values negatively affect the quality of the mesh representation. In particular, small changes are a favorable precondition for subsequent optimization steps. Therefore, it is not ruled out, however, that the maximum spatial change can be locally defined. An upper limit value for the optimization in the FEM calculation is established by means of the maximum spatial change. The maximum spatial change implicitly yields the size ratios of the element size values of adjacent geometric basic elements of the mesh representation. Adjacent geometric basic elements can therefore be larger or smaller than their neighbors only in an area defined by the maximum spatial change. The desired maximum ratio between adjacent geometric basic elements can be approximately achieved, for example, by defining a maximum linear slope of the distribution of the element size values across the space.

In an optional further step 110, the method 100 for the digital representation of the object can determine a predefined spatial distribution of a lower limit for the element size value, which is additionally a lower limit for the local maximum limit.

In the ideal case, the lower limit can be determined such that the required accuracy of the subsequently performed simulation is just barely reached. In certain time-dependent calculations, the smallest geometric basic element in the mesh representation specifies the time increment. Small geometric basic elements require small time increments and, therefore, more computing time. For the preceding definition of the lower limit, the computing time can be weighed against the achievable accuracy. Preferably, a global value can be predefined for the lower limit. In areas, about which it is already known that large geometric basic elements do not significantly negatively affect the accuracy of the simulation, for example, higher values can be defined for the lower limit. This can apply, for example, for areas that are secondary for the interpretation of the simulation results and/or that have only small effects on the global simulation result and/or in which no relevant effects are to be expected. The lower limit can be, for example, defined by the user or specified by an evaluation plan. In addition, the lower limit can be defined, for example, in a material-specific manner.

In FIG. 2b, multiple ranges 42 through 50 are shown, each of which represents a lower limit. The dashed line in each case represents the particular lower limit. The shading below the dashed line represents an area, in which element size values are not to be located. In the ranges 42 through 48, the lower limit is globally defined, i.e., is constant. In the range 50, the lower limit decreases from left to right, i.e., the lower limit is not constant in this range. In addition, ranges in which a lower limit has not been defined can also be arranged between the ranges, in which a lower limit has been defined. This is the case, for example, between the ranges 44 through 50. Between the ranges 42 through 44, there are no ranges in which a lower limit has not been defined. The lower limit can be discontinuous at the transition between the ranges, regardless of whether or not a lower limit has been defined in the particular range.

The ranges, in which an upper limit has been defined, and in which a lower limit has been defined, must not overlap. For example, the range 50 is wider than the range 38. In addition, the range 44 overlaps with a range, in which an upper limit has not been defined.

Local maximum limits can also be defined in areas, in which an upper limit and/or a lower limit have/has been defined, or in which neither an upper limit nor a lower limit has been defined.

In addition, local maximum limits can be greater than the upper limit defined at the particular position or less than the lower limit defined at the particular position.

In one further step 108, a spatial distribution of element size values for the digital object representation is determined on the basis of the local maximum limit, the predefined spatial distribution of the upper limit and on the predefined spatial distribution of the maximum spatial change. In this example, the lower limit is taken into account in the determination. It is optional, however, to provide a lower limit or to take a lower limit into account.

Local maximum limits that are greater than the upper limit are not taken into account in the determination of the spatial distribution of element size values. The positions 18 and 20 are examples thereof. Local maximum limits that are less than the lower limit are increased to such an extent that they are situated at the lower limit. This has taken place, for example, with the maximum value 54 at the position 28.

For this purpose, in an optional substep 112, a maximum possible element size value can be determined for each position of the digital representation of the object, the maximum possible element size value being based at least on the local maximum limit, the predefined spatial distribution of the upper limit and the predefined spatial distribution of the maximum spatial change. The spatial distribution 52 of the element size values shown in FIG. 2d can be determined, for example, in this way.

For this purpose, a spatial progression of the element size values 52 can be determined by means of the maximum spatial change starting from the lowest permitted element size value, which is determined by the local maximum limit at the position 26. The spatial progression 52 is situated at the local maximum limits at the positions 16 and 28. At the positions 18, 20, 22 and 24, the spatial progression 52 extends below the local maximum limit, since the maximum spatial change does not permit the spatial progression 52 to have a slope that enables the local maximum limits to be reached at these positions.

When the spatial progression 52 in this example hits an upper limit, such as, for example, in the ranges 36 and 38, said spatial progression extends along this upper limit.

The step 108 can also include the optional substeps 114, 116 and 118.

When a local maximum limit has been determined for a position in the digital representation, in the optional substep 114, at least one fixed point for an element size value is set at the local maximum limit at this position in the digital representation of the object. A fixed point can therefore also be referred to as a fixed point.

Fixed points at the positions that have a local maximum limit are marked as x's in FIG. 2b.

Thereafter, the optional substep 118 can be carried out, with which a spatial distribution of element size values is determined on the basis of the fixed points and the spatial distribution of the maximum spatial change. In the determination of the spatial distribution 52 of the element size values, fixed points can be situated on the spatial distribution 52 or fallen below by said spatial distribution. An exceedance is all that is not permitted. This is also shown in FIG. 2b by means of the spatial progression 52 of the element size values. Upper limits or lower limits are not taken into account.

The optional substep 116 can also be carried out prior to or after the optional substep 118. In the optional substep 116, a fixed point for the element size values is set at further positions of the digital representation of the object, said fixed point having, at most, a value of the upper limit. This means, the fixed point that is set in the optional substep 116 can also be less than the upper limit.

After the optional substep 116, the optional substep 118 can be carried out again or, when the optional substep 116 has been carried out immediately after or simultaneously with the optional substep 114, the optional substep 118 can be carried out.

The optional substeps 114, 116 and 118 can be carried out in any order or simultaneously, provided this is logically meaningful.

The optional substep 116 can also include the optional sub-substep 120. In the optional sub-substep 120, a fixed point for the element size values is set at the upper limit at positions, at which the spatial distribution of the upper limit has a discontinuity.

Generally these positions are arranged at the edges of the areas 30 through 38. It goes without saying that a discontinuity in the progression of the upper limit can also be present within a range, in which an upper limit has been defined.

The optional substep 116 can also include the optional sub-substeps 122, 124 and 126.

In the optional sub-substep 122, a spatial distribution of preliminary element size values in the digital representation of the object is determined on the basis of the fixed points that were determined in the substep 114, and on the spatial distribution of the maximum spatial change. FIG. 2b can serve as an example of this step. The spatial distribution 52 of the element size values shown in FIG. 2b must then be considered merely as a spatial distribution of the preliminary element size values.

According to the optional sub-substep 124, the preliminary element size values are set at the upper limit at the positions in the digital representation of the object, at which the preliminary element size values are greater than the upper limit. This is shown, for example, in FIG. 2c at the right end of the ranges 36 and 38 in comparison to FIG. 2b.

In the subsequent optional sub-substep 126, a fixed point for the element size values is set at the preliminary element size values at the positions, at which a discontinuity is now present in the spatial distribution of the preliminary element size values or a discontinuity is now present in the spatial distribution of the upper limit. In FIG. 2c, these fixed points are the fixed points 56 and 58.

In addition, the optional substeps 116 and 118, either individually or both together, can have the optional sub-substep 132. In the optional sub-substep 132, the set fixed points are stored in a priority queue. This facilitates the processing of the fixed points in the determination of the spatial distribution of the element size values.

After the optional step 118, the step 108 can also include the optional substep 130. In the optional substep 130, element size values that are greater than the upper limit for the same position are set at the upper limit. The optional substep 130 is carried out primarily when a spatial distribution of preliminary element size values was not determined according to the optional sub-substeps 122 through 126.

The step 108 can also include the optional substep 128, in which fixed points are removed. Fixed points are removed when the fixed point is greater than an element size value determined for the position of the fixed point. In addition, the fixed point can be removed when the fixed point is greater than or equal to an element size value determined for the position of the fixed point by means of at least on other fixed point. The removal of fixed points is equivalent to not taking fixed points into consideration in the determination of the spatial distribution of the element size values.

According to the first condition, fixed points are therefore removed when the fixed points do not affect the element size value at its position after the spatial distribution of the element size values has been determined. This means, when the fixed points do not bring about greater element size values in the spatial distribution under consideration of the maximum spatial change.

According to the second condition, fixed points are removed when, due to other fixed points, the spatial distribution of the determined element size values at the position of the fixed points to be removed result in element size values that are equal to or less than the particular fixed point to be removed.

In addition, the step 108 can include the optional substeps 134, 136, 138 and 140.

In the optional substep 134, the digital object representation is divided into at least two areas. The at least two areas are interconnected via a border region. In the one-dimensional case, this border region includes at least one point that connects the two areas to each other. Points adjacent to this point can also belong to the border region. In the two-dimensional or three-dimensional case, the border region can therefore additionally include at least one straight or curved line or, further additionally, have a planar or curved surface.

In FIG. 2b, a border region is marked, for example, at the position 60. The two areas of the digital object representation are located to the right and the left of the position 60.

In the optional substep 136, an element size value is determined for at least one position in the border region 60. In FIG. 2b, this element size value is indicated with reference sign 62.

In the further optional substep 138, the element size value 62 determined in the border region 60 is set as a fixed point 64, as indicated in FIG. 2c.

In the optional substep 140, the spatial distribution of element size values is determined individually for each area. In the area to the right of the border region 60, the fixed point 64 and the further fixed points located in this area are used for this purpose. Likewise, in the area to the left of the border region 60, the fixed point 64 and the further fixed points located in this area are used for determining the spatial distribution of the element size values in this area. Of course, the maximum spatial change in the determination of the spatial progression of the element size values is taken into account in both areas.

With the optional substeps 134 through 140, computing time can be saved due to the area-based determination of the spatial progressions of the element size values, since fewer fixed points need to be taken into account for every single area.

In addition, the step 108 can include the optional substeps 142, 144, 146, 148 and 150.

The optional substeps 142 and 144 are similar to the optional substeps 114 and 116.

In the optional substep 142, fixed points for the element size values are set at the positions, at which local maximum limits have been determined. In the optional substep 144, fixed points for the element size values are set at further positions, wherein the fixed points then have, at most the value of the upper limit. The optional substeps 142 and 144 can be provided either individually or together.

Thereafter, the digital representation of the object is subdivided into at least two areas in the optional substep 146, wherein these two areas are interconnected by means of at least one border region. This takes place similarly to the optional substep 134.

In the optional substep 148, at least one border region fixed point is determined in the border region by means of the previously determined fixed points outside the border region. For each border region fixed point, the corresponding element size value and/or which previously determined fixed points are decisive for the determination of the border region fixed point is/are stored. Only those previously determined fixed points are decisive that bring about an upper limitation of the border region fixed point in conjunction, for example, with the maximum spatial change, the upper limit and/or the lower limit.

Thereafter, in the optional substep 150, the spatial distribution of element size values is determined separately for at least one of the at least two areas. The determination is based on the at least one border region fixed point. When further fixed points are located in the corresponding area, these fixed points are also taken into consideration.

The method 100 can also include the optional steps 154 and 156.

In the optional step 154, a spatial distribution of geometric basic elements for a mesh representation of the digital object representation is determined on the basis of the determined spatial distribution of the element size values for the digital object representation. The geometric basic elements can be selected such that the digital object representation is optimally reproduced and the computing time is optimized for a subsequent simulation. The size of the geometric basic elements corresponds at each point to the element size value, which applies for this point, from the spatial distribution of the element size values.

In the optional step 156, the mesh representation for the digital representation of the object is then determined from the determined spatial distribution of the geometric basic elements. The geometric basic elements are connected in this optional step to form a mesh representation. For this purpose, the geometric basic elements can be interconnected via individual or multiple points, individual or multiple lines and/or individual or multiple faces. The simulation of the material properties can then be carried out using this mesh representation.

According to this example, geometries can be used in the enmeshment that have been detected using various sensors or that originate from CAD models.

According to one further example, the global minimum of the lower limit can be initially determined. On the basis thereof, a resolution can be determined for the spatial distribution of the element size values. This can be, for example, three-fold as great as this value. In this way, the spatial distribution is prevented from having a resolution that is too fine, which would lengthen the computing time while, simultaneously, the necessary resolution is not fallen below. In addition, the global minimum of the local maximum limit can also be taken into account.

According to another example, the upper limit and the lower limit can be estimated on the basis of a previously carried-out simulation, for example, on the CAD model of the object to be investigated.

In addition, a value for the resolution can be estimated, for example, on the basis of the global minimum of the lower limit and/or of the local maximum limit.

When the digital representation of the object has a multi-material geometry, the spatial distribution of the upper limit and the spatial distribution of the maximum local change of the element size values can be material-dependent. Alternatively or additionally, the step 104 can be carried out in a material-dependent manner.

The invention is not limited to one of the above-described embodiments, but rather is modifiable in various ways. All features and advantages, including design details, spatial arrangements and method steps, resulting from the claims, the description and the drawing may be essential to the invention alone or in highly diverse combinations.

1. A computer-implemented method for determining a spatial distribution of element size values for geometric basic elements of a mesh representation from a digital representation of an object for a simulation of the object, wherein the mesh representation contains a plurality of interconnected geometric basic elements, wherein the method includes the following steps:
determining a digital representation of an object;
determining, for at least one position of the digital representation of the object, at least one local maximum limit for the element size values that depends on at least one local geometric property in an area surrounding the position;
determining, for the digital representation of the object, a predefined spatial distribution of an upper limit, independent of the at least one local maximum limit, for the element size values and a predefined spatial distribution of a maximum spatial change in the element size values; and
determining a spatial distribution of element size values for the digital object representation on the basis of the local maximum limit, the predefined spatial distribution of the upper limit and the predefined spatial distribution of the maximum spatial change.

2. The method as claimed in claim 1, wherein the method also includes the following step:
determining, for the digital representation of the object, a predefined spatial distribution of a lower limit for the element size value, which is additionally a lower limit for the local maximum limit.

3. The method as claimed in claim 1, wherein the step determining a spatial distribution of element size values includes the following substep:
determining, for each position of the digital representation of the object, a maximum possible element size value, which is based at least on the local maximum limit, the predefined spatial distribution of the upper limit and the predefined spatial distribution of the maximum spatial change.

4. The method as claimed in claim 1, wherein the step of determining a spatial distribution of element size values on the basis of the local maximum limit, the predefined spatial distribution of the upper limit and the predefined spatial distribution of the maximum spatial change includes, for example, the following substeps:
setting at least one fixed point for an element size value at at least one position in the digital representation of the object at the local maximum limit when a local maximum limit has been determined for this at least one position in the digital representation;
setting at least one fixed point for an element size value at at least one further position in the digital representation of the object that has a value of, at most, the upper limit; and
determining the spatial distribution of element size values on the basis of the fixed points and the spatial distribution of the maximum spatial change.

5. The method as claimed in claim 4, wherein the substep of setting at least one fixed point for an element size value at at least one further position in the digital representation of the object that has a value of, at most, the upper limit, includes the following sub-substep:
setting at least one fixed point for an element size value at the upper limit at at least one position in the digital representation of the object, at which the spatial distribution of the upper limit has a discontinuity.

6. The method as claimed in claim 4, wherein the substep of setting at least one fixed point for an element size value at at least one further position in the digital representation of the object that has a value of, at most, the upper limit, includes the following sub-substeps:
determining a spatial distribution of preliminary element size values in the digital representation of the object on the basis of fixed points that have been determined in the substep of setting at least one fixed point for an element size value at at least one position in the digital representation of the object at the local maximum limit when a local maximum limit has been determined for this at least one position in the digital representation, and the spatial distribution of the maximum spatial change;
setting the preliminary element size values at the upper limit at positions in the digital representation of the object, at which the preliminary element size values are greater than the upper limit; and
setting at least one fixed point for an element size value at the preliminary element size value at at least one position in the digital representation of the object, at which the spatial distribution of the upper limit and/or the spatial distribution of preliminary element size values has a discontinuity.

7. The method as claimed in claim 4, wherein the step of determining a spatial distribution of element size values also includes the following substep:
removing the fixed point when the fixed point is greater than an element size value determined for the position of the fixed point and/or when the fixed point is greater than or equal to an element size value determined for the position of the fixed point by means of at least one further fixed point.

8. The method as claimed in claim 4, wherein the step of determining a spatial distribution of element size values according to the substep of determining the spatial distribution of element size values on the basis of fixed points and the spatial distribution of the maximum spatial change includes the following substeps:
setting the element size values of the determined spatial distribution of element size values, which are greater than the upper limit for the same position, on the upper limit.

9. The method as claimed in claim 4, wherein at least one of the following substeps:
setting at least one fixed point for an element size value at at least one further position in the digital representation of the object that has a value of, at most, the upper limit; and/or
determining the spatial distribution of element size values on the basis of the fixed points and the spatial distribution of the maximum spatial change;
also have the following sub-substep:
storing the set fixed points in a priority queue.

10. The method as claimed in claim 1, the step of determining a spatial distribution of element size values for the digital object representation on the basis of the local maximum limit, the predefined spatial distribution of the upper limit and the predefined spatial distribution of the maximum spatial change includes the following substeps:
setting at least one fixed point for an element size value at at least one position in the digital representation of the object at the local maximum limit when a local maximum limit has been determined for this at least one position in the digital representation; and/or setting at least one fixed point for an element size value at at least one position in the digital representation of the object that has a value of, at most, the upper limit;
dividing the digital representation of the object into at least two areas, wherein at least two areas in each case are interconnected by means of a border region;
determining at least one border region fixed point for at least one position in the at least one border region on the basis of the previously determined fixed points outside the border region, wherein, for each border region fixed point value, an element size value and/or a piece of information about at least one previously determined fixed point, which is decisive for the particular border region fixed point, is determined and stored; and
determining a spatial distribution of element size values for at least one of the two areas separately on the basis of the at least one border region fixed point and, when further fixed points are arranged in the area, preferably at the further fixed points.

11. The method as claimed in claim 1, wherein the step of determining, for at least one position of the digital representation of the object, a local maximum limit for the element size value that depends on at least one local geometric property in an area surrounding the position, includes the following substep:
determining the local maximum limit for the position on the basis of a local curvature of a surface of the digital representation of the object at the position, a local wall thickness of the digital representation of the object at the position and/or a previously carried out simulation result for the object.

12. The method as claimed in claim 1, wherein the digital representation of the object has a multi-material geometry, wherein the spatial distribution of the upper limit, the spatial distribution of the maximum local change in the element size values and/or the step of determining, for at least one position of the digital representation of the object, a local maximum limit for the element size value that depends on at least one local geometric property in an area surrounding the position, are material-dependent.

13. The method as claimed in claim 1, wherein the digital representation of the object is determined by means of a computed tomographic measurement of the object.

14. The method as claimed in claim 1, wherein the method also includes the following steps:
determining a spatial distribution of geometric basic elements for a mesh representation of the digital representation of the object on the basis of the determined spatial distribution of element size values; and
determining a mesh representation for the digital representation of the object from geometric basic elements on the basis of the determined spatial distribution of geometric basic elements.

15. A computer program product having instructions, which can be carried out on a computer and, when carried out on a computer, prompt the computer to carry out the method as claimed in claim 1.
